(19) United States
(12) Patent Application Publication
(10) Pub. No.: US 2024/0389476 A1
(43) Pub. Date: Nov. 21, 2024

(54) HIGH TEMPERATURE SUPERCONDUCTING DEVICES AND METHODS THEREOF

(71) Applicant: The Regents of the University of California, Oakland, CA (US)

(72) Inventor: Shane Cybart, Corona, CA (US)

(21) Appl. No.: 18/667,120

(22) Filed: May 17, 2024

Related U.S. Application Data
(60) Provisional application No. 63/503,362, filed on May 19, 2023.

(51) Int. Cl. H10N 60/01; G01Q 60/40; H10N 60/12

(52) U.S. Cl. CPC H10N 60/0941; H10N 60/124; G01Q 60/40

(57) ABSTRACT

A high temperature superconducting device including a substrate, a high temperature superconducting thin film disposed on the substrate and one or more non-superconducting thin film regions formed adjacent to and across a substantially entire thickness of the high temperature superconducting thin film. In the high temperature superconducting device, the one or more non-superconducting thin film regions are formed from degrading corresponding superconducting materials same to the high temperature superconducting thin film through applying an external voltage. In addition, the one or more non-superconducting thin film regions and the high temperature superconducting thin film form one or more Josephson tunnel junctions.

### CROSS-REFERENCE TO RELATED APPLICATION(S)

This application claims the benefit of U.S. Provisional Application No. 63/503,362, filed May 19, 2023.

### TECHNICAL FIELD

The present disclosure generally relates to high temperature superconductors (HTS) device fabrication, and more particularly relates to applying external voltages through a nanoscale probe tip to high temperature superconducting material to produce superconducting tunneling devices.

### BACKGROUND

High temperature superconductors (HTS) exhibit superconductivity at temperature above the boiling point of liquid nitrogen and offer many advantages over conventional low-temperature superconductor because its cooling requirements are easier to satisfy. The ability to maintain superconductivity at higher temperatures unlocks significant potential for a variety of practical applications. These applications span across diverse fields such as superconducting electronics, magnetic resonance imaging (MRI), and energy storage systems. The unique properties of HTS have the potential to revolutionize these areas by improving efficiency, reducing energy losses, and enabling the development of new technologies.

The fabrication of HTS devices typically involves a series of intricate processes, such as photolithography and etching procedures, to pattern the HTS material. The patterning is a critical step in the creation of superconducting devices, including the production of Josephson tunnel junction devices, which are fundamental components in superconducting electronics. Josephson tunnel junctions are known for their ability to control electrical current with high precision, making them essential for the functionality of superconducting circuits. In Josephson tunnel junctions, electrical transport occurs within the plane of a thin film composed of superconducting material. The HTS thin film is usually shaped using a combination of photolithography and dry ion etching techniques. These methods are adopted at defining large circuit features. However, when it comes to the formation of Josephson tunnel junctions, alternative approaches are often employed. One such approach involves the direct writing of circuits onto the superconducting material. This can be achieved by transforming specific regions of the superconducting material into an insulator, e.g., by a reported process accomplished using focused electron or ion beams. However, the processes described above are usually costly and time-consuming. For instance, ion beam circuits are restricted to a thickness of approximately 40 nm due to the need to project the beam through the material, which in turn limits the electrical properties and possible configurations of the HTS devices.

### BRIEF SUMMARY

The present disclosure describes some embodiments that adopt a probe having a conductive nanoscale tip and to apply high voltages through the nanoscale tip to HTS materials in order to achieve the superconductor-insulator transition. In particular, the present disclosure discloses a technique to directly write circuits into HTS material by converting certain regions of the HTS material to an insulator, through applying an external voltage. Specifically, an Atomic Force Microscopy (AFM) test tool equipped with a nanoscale tip can be operated in a high voltage mode and adopted for the superconductor-insulator transition. The AFM tip can scan on the HTS material and apply the high voltage along a certain trace thereon to fabricate Josephson junction structures within the HTS material. The HTS material can be written similarly to processes using complex photolithography or ion beam etching techniques. By carefully controlling of the nanoscale tip scan path and scan speed, high quality HTS Josephson superconducting tunnel junction device can be fabricated in a faster and cheaper method with a better resolution.

A superconducting device is described in the present disclosure. In some implementations, the superconducting device includes a substrate, a superconducting thin film disposed on the substrate, and one or more non-superconducting regions formed adjacent to and across a substantially entire thickness of the superconducting thin film. The superconducting thin film has the substantially entire thickness configured to allow an external voltage to directly write one or more non-superconducting regions in the superconducting thin film to form one or more Josephson tunnel junctions.

In another general aspect, an apparatus for fabricating superconducting devices is described in the present disclosure. The apparatus for fabricating superconducting devices includes a sample stage configured to hold a superconducting sample and a power source configured to provide direct current (DC) voltages or an alternative current (AC) voltages. The apparatus also includes one or more cantilevers connected to the power source and one or more conductive nanoscale tips disposed on one end of corresponding one or more cantilevers. The one or more conductive nanoscale tips are configured to scan along a frontside surface of the superconducting sample while applying a DC voltage or an AC voltage provided by the power source. In addition, one or more non-superconducting regions are formed in the superconducting sample depending on scan path of the one or more conductive nanoscale tips.

In another general aspect, a method of forming a superconducting device is described in this disclosure. The method of forming a superconducting device includes depositing a superconducting thin film on a substrate and forming one or more contact electrodes that are electrically connected to the superconducting thin film. The method also includes applying an external voltage on a tip and approaching the tip to a frontside surface of the superconducting thin film. The method further includes scanning the tip above the superconducting thin film to form one or more non-superconducting regions within the superconducting thin film.

### BRIEF DESCRIPTION OF THE DRAWINGS

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

FIGS. 1A and 1B depict a crystal structure of YBa₂Cu₃O_{7-δ} (YBCO) high temperature superconductor material and resistivity of YBCO high temperature superconductor material as a function of temperature, respectively.

FIG. 2A depicts a micrograph of an ion irradiated nano-SQUID directly written into a YBCO sample with a thickness of 40 nm. FIG. 2B show AFM images illustrating topography of the irradiated regions of the YBCO sample.

FIG. 3A depicts a gold coated YBCO sample that is chip wire bonded into a package for the processing, according to various embodiments of the present technology.

FIG. 3B depicts a top down view of a YBCO high temperature superconductor film covered by gold top electrodes for Josephson devices fabrication, according to various embodiments of the present technology.

FIG. 3C depicts a nanoscale tip scanning through a YBCO high temperature superconductor film and converting the YBCO film from superconductor to insulator, according to various embodiments of the present technology.

FIGS. 4A and 4B show an optical image and a height image of a YBCO high temperature superconductor film before applying external voltages, respectively according to various embodiments of the present technology.

FIGS. 4C and 4D show an optical image and a height image of the YBCO high temperature superconductor film shown in FIGS. 4A and 4B after applying an external +9 volts voltage through scanning an AFM nanoscale tip, respectively according to various embodiments of the present technology.

FIGS. 5A and 5B show a height image and a current image of a YBCO high temperature superconductor film after an AFM nanoscale tip scan with an applied +9 volts voltage, respectively according to various embodiments of the present technology.

FIG. 6 shows an image of overlapped height and current modes of a YBCO high temperature superconductor film sample where some regions have been converted to insulator after applying a +9 volts voltage using a nanoscale AFM tip, according to various embodiments of the present technology.

FIGS. 7A and 7B show a height image and a current image of a YBCO high temperature superconductor film after an AFM nanoscale tip scan with a negative voltage, respectively according to various embodiments of the present technology.

FIG. 8 shows an image of overlapped height and current modes of a YBCO high temperature superconductor film sample where some regions have been converted to insulator after applying a negative voltage using a nanoscale AFM tip, according to various embodiments of the present technology.

FIG. 9 depicts energy maps of YBCO high temperature superconductor films plotted as a function of the angle of electrode in the plane. FIG. 9A shows an expected 2:1 anisotropy for the a and b axes, FIG. 9B shows an isotropic disordered configuration, and FIG. 9C shows a uniaxial anisotropy. FIG. 9D shows an ion radiated YBCO thin film sample in a 25 μm field of view, FIG. 9E and FIG. 9F show other ion radiated YBCO thin film samples of FIGS. 9B and 9C respectively in a 5 μm field of view.

FIGS. 10A and 10B depict a topography image and a current image of a Europium-doped ZnO thin film sample at a bias of 1.5 volts and 2 μm scan region. FIG. 10C shows corresponding current-voltage curve recorded at three specific positions indicated in FIG. 10B.

FIGS. 11A and 11B depicts schematic views of applying a voltage through a nanoscale tip to form current along the in-plane direction of HTS film (FIG. 11A) or the out-of-plane direction of HTS film (FIG. 11B) for Josephson-junction devices fabrication, according to various embodiments of the present technology.

FIG. 12 is a flow chart illustrating a method for fabricating a HTS device in accordance with various embodiments of the present technology.

### DETAILED DESCRIPTION

HTS materials exhibit highly anisotropic electrical transport properties, their conductivity along the c-axis being several orders of magnitude lower than that in the a-b plane. This further complicates device fabrication because the highest quality HTS films have c-axes oriented normal to the substrate. Researchers have searched for a method to fabricate superconducting tunnel junctions from these materials for both superconducting electronics operating at the practical temperature of liquid nitrogen (about 77 K) and for fundamental measurements essential for testing and guiding theories of these remarkable superconductors. For example, high transition temperature superconductors like YBaCuO can exhibit superconductivity at much higher temperature than elemental superconductors.

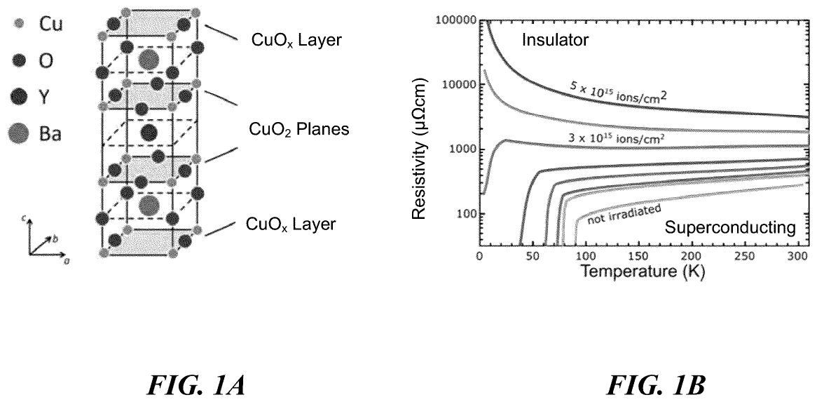

FIG. 1 illustrates the most commonly studied oxide superconductor YBCO that crystallizes in an orthorhombic unit cell with a distorted perovskite structure: in the center is a single yttrium atom flanked by two copper oxygen planes. It is widely accepted that strong interaction between electrons in these planes is key to the superconducting state. Electrons are strongly coupled for k-space directions parallel to the Cu—O—Cu bonds, but weakly coupled in k-space directions along the diagonals. This gives rise to the anisotropy in the superconductivity. The superconducting coherence length in YBCO is less than 0.2 nm along the c-axis and 2-3 nm in the a-b plan. In YBCO, the copper oxide chains run along the top and bottom of the unit cells along the b directions and contribute to electrical transport.

The crystal structure of oxide superconductors is sensitive to point defects caused by ion irradiation. FIG. 1B shows the resistivity of YBCO films irradiated with 75 keV helium ions as a function of temperature for seven doses of irradiation. With increasing dosage, the resistivity rises and Tc decreases. For irradiation exceeding 3×10¹⁵ ions/cm², the material becomes a disordered insulator. The irradiation induced metal-to-insulator transition (MIT) in the normal state comes about because the electron mean free path is sensitive to the disorder of the oxygen lattice. Disorder shortens the mean free path and increases resistivity. Disordered YBCO has lesser a and b directional anisotropy in electrical resistivity than non-irradiated YBCO. In the present technology, externally voltage can be applied to cause the metal-to-insulator transition in the YBCO film, through disordering the oxygen lattice chain structure and shortening the mean free path thereof.

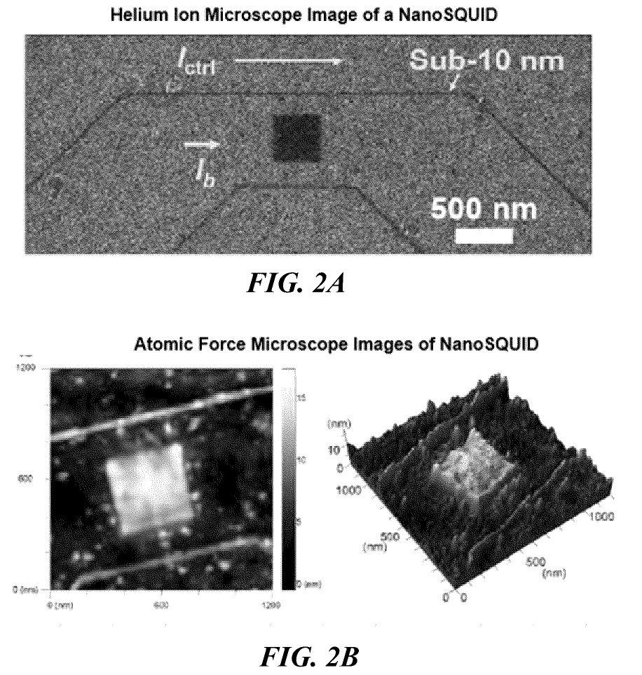

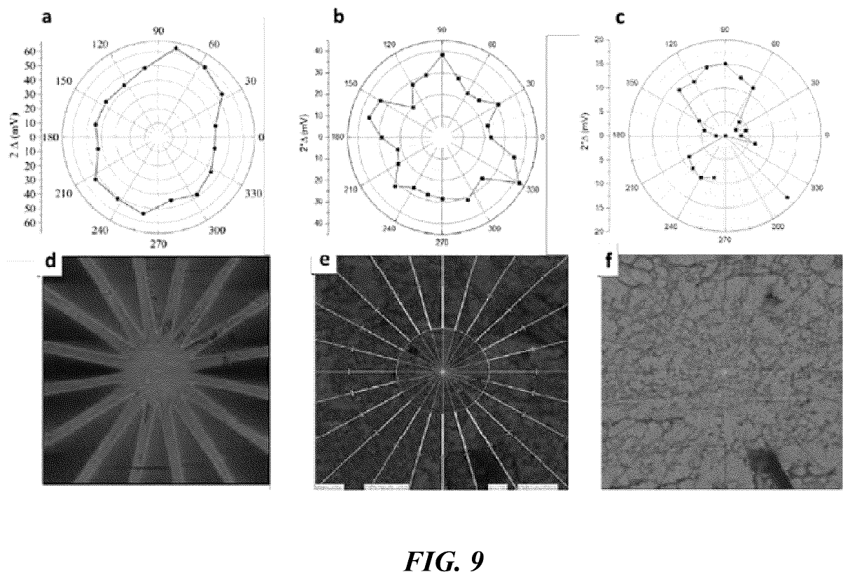

However, the above described complex oxide materials are ceramics that are difficult to fabricate into electronic devices, because the material has a large anisotropy that eliminates classical sandwich type Josephson junction structures. Prior arts utilize methods that create planar type junctions where electrical transport is inside the plane of a thin superconducting film of material. The film is typically structured using photolithography and dry ion etching to pattern large circuit features and to form Josephson tunnel junctions. For example, both electron beam irradiation and masked ion implantation have long been used as methods to fabricate Josephson tunnel junctions. A finely focused ion beam has been adopted to demonstrate patterning of large and fine features in HTS material. See U.S. Pat. No. 11,063,201 B2. For example, FIGS. 2A and 2B show a micrograph of an ion irradiated nano-SQUID directly written into a YBCO sample with a thickness of 40 nm and AFM images illustrating topography of the irradiated regions of the YBCO sample, respectively. The helium ion microscope image, depicted in FIG. 2A, shows a nano-SQUID with a 400 nm loop and features insulating lines with widths under 10 nm, which are directly written onto the YBCO film using the helium ion microscope. These insulating lines are critical for defining the electrodes of the device, while the Josephson tunnel junctions are represented as faint vertical lines adjacent to the central square. In complementing, FIG. 9B presents a conventional atomic force microscopy (AFM) image that reveals the topographical changes post-fabrication, indicating a mechanical elevation of the YBCO film by approximately 10 nm due to the ion irradiation process. This elevation corresponds to a significant 25% increase relative to the original YBCO film thickness, providing insight into the effects of ion irradiation on the HTS device's surface characteristics. The superconducting Josephson tunnel junctions have suffered from very small characteristic voltages V_{C}=I_{C}R_{N} (a figure of merit for Josephson tunnel junctions equal to the product of the critical current and the normal state resistance) that precludes their use in most applications. Another drawback to these ion irradiated Josephson tunnel junctions is the presence of a large non-Josephson excess current at zero voltage that does not exhibit either the DC or AC Josephson effects.

The significance of using the focused ion beam over other ion beams previously demonstrated is that it has a very fine resolution of about 1 nm which enables quantum tunnel devices. However, challenges for this finely tuned ion beam irradiation technique are that the manufacturing cost is high and processing time could be very long, therefore not fitting to volume manufacturing. Accordingly, the need remains for a method for fabricating Josephson tunnel junctions and other devices with nanometer-scale dimensions. The present disclosure is directed to such a method.

According to embodiments of the present technology, high-quality HTS Josephson superconducting tunnel junctions, arrays and superconducting quantum interference devices can be created by scanning a surface of the device using a tip having approximately 1 nm to 10 nm diameter and applying a voltage through the tip to direct-write superconducting films into insulating or poorly conducting barriers. The examples described herein is not limited to DC voltages, AC voltage can also be adopted in the present disclosure for Josephson tunnel junction device fabrication.

In the present technology, the alteration of the HTS material can be regular and according to the timing and positioning of the tip. For example, by precisely managing the scanning path and duration of the tip's contact, the HTS material can be patterned in a manner akin to ion beam material writing. This technique offers a faster, more cost-effective, and potentially higher-resolution alternative to the current HTS device fabrication processes.

A distinct and innovative aspect of the present technology is the utilization of a nanoscale tip to apply a substantial voltage to a HTS film (e.g., a YBCO thin film), inducing a material transformation that eliminates superconductivity and that converts the material into insulator. In the present technology, a software can be implemented to control the tip's position, voltage, and duration, to enable the direct inscription of insulative patterns into the HTS film. The areas that retain superconductivity subsequently constitute the HTS device/circuit. With the application of a higher voltage (e.g., voltages higher than +9 volts or lower than −9 volts), the present technology is capable of patterning thicker HTS materials, transitioning them from superconducting to insulating states. The present technology is also applicable to HTS circuits with lower sheet inductance and higher critical currents.

In the present disclosure, the examples described include YBa₂Cu₃O_{7-δ} (YBCO) thin films. However, any other superconducting material may also be processed in this way to form Josephson tunnel junctions and nanowires. For example, high temperature superconductors made of Yttrium Barium Copper Oxide (YBa₂Cu₃O₇₋ₓ), Bismuth Strontium Calcium Copper Oxide (Bi₂Sr₂CaCu₂O₈₋ₓ), Thallium Barium Calcium Copper Oxide (Tl₂Ba₂Ca₂Cu₃Oₓ), Mercury Barium Calcium Copper Oxide (HgBa₂Ca₂Cu₃O₈₊ₓ), Magnesium Diboride (MgB₂), and a combination thereof can be adopted for the Josephson junction devices fabrication. In another example, superconducting nanowire can be formed by surrounding at least two non-superconducting regions on its ends, within a superconducting thin film. In the present disclosure, the HTS thin film may have a thickness up to 100 nm. For example, the HTS YBCO thin film disclosed in the present disclosure can have a thickness up to 1 nm. In some other examples, the HTS YBCO thin film disclosed in the present disclosure can have a thickness ranging from 1 nm to 10 nm. In some other examples, the HTS YBCO thin film disclosed in the present disclosure can have a thickness ranging from 10 nm to 100 nm.

This technique presented in this disclosure provides a reliable and reproducible pathway to conduct superconducting tunneling studies in HTS, as well as an avenue for the scaling up of quantum mechanical circuits operating at practical temperatures. In addition, the described method is applicable to virtually any electronic device that is based on formation of a tunnel junction in a material that is sensitive to disorder, for example magnetic tunnel junctions (e.g., multiferroic, manganite, graphene, etc.) for spintronic circuits, and semiconductor junctions. The inventive method enables the fabrication of junctions that are strong and narrow, avoiding the limitations of conventional proximity effect Josephson tunnel junctions, including small I_{C}R_{N}, large reduction in wave function amplitude, and lack of quasiparticle tunneling.

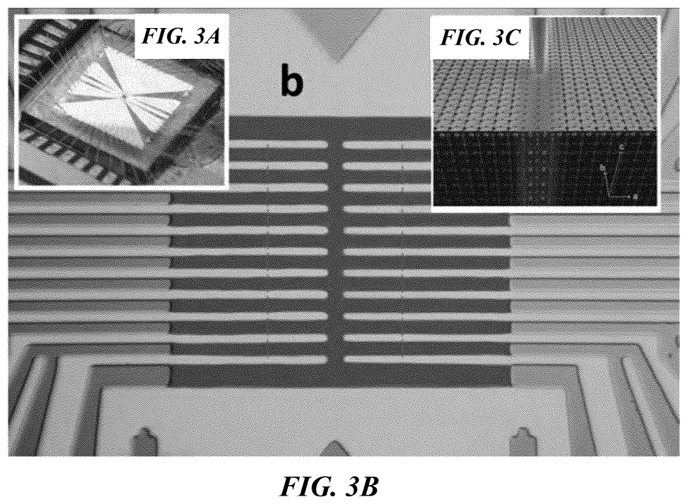

The basic Josephson tunnel junction HTS devices fabricated by the present technology are shown in FIGS. 3A to 3C. FIGS. 3A provides a photo micrograph of an exemplary device fabricated using the inventive process. To fabricate Josephson tunnel junctions, large circuit features for electrical contacts and wide strips of YBCO were patterned using photolithography in a YBCO thin film on a 5 mm×5 mm sapphire substrate that had an in situ deposited conductive contact layer on top. In the described example, gold (Au) is used, but selection of other conducting films, such as silver, palladium, platinum would be readily apparent to one of skill in the art. Here, YBCO films having a thickness up to microns can be grown using reactive co-evaporation on cerium oxide buffered sapphire wafers. For electrical contacts, 200 nm of gold can be sputtered onto the film before breaking vacuum. Wafers can be further diced into 5 mm×5 mm substrates and form patterned Au electrode above the YBCO layer using photolithography techniques. As shown in FIG. 3B, nanoscale AFM tips can be programmed to scan along the vertical lines and across the pattered YBCO film.

The initial YBCO film thickness may be large, but after the Au electrode was removed the YBCO film underneath can be etched to a thickness around 30 nm in the area intended for junctions. Reducing the thickness of the YBCO was determined to be essential to the success of this method because it was important that the applied external voltage is proportional to the thickness of the YBCO film. FIG. 3C illustrates the scanning of nanoscale tip above the YBCO film, which converts the HTS YBCO from superconductor to insulator.

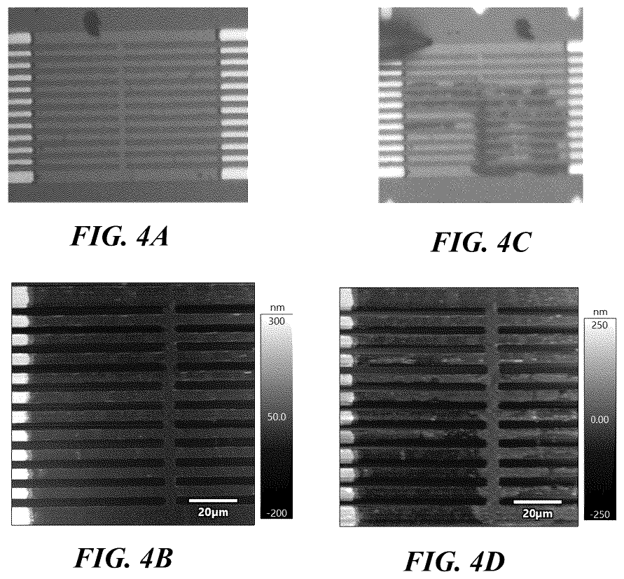

In the present technology, an appropriate nanoscale tip can be installed in on AFM probe or cantilever. The nanoscale tip can be connected to a voltage source and scan along a frontside surface of a HTS film to fabricate the Josephson tunnel junction devices. FIGS. 4A and 4C respectively shows optical images of a HTS YBCO film before and after applying a +9 volts voltage through a nanoscale tip of an AFM tool. In comparison to incoming patterned YBCO films on FIG. 4A, the HTS YBCO film shows dark regions in areas which the nanoscale tip has scanned. The color change of the YBCO film shown in FIG. 4C confirms the material degradation and disorder after applying external voltages. Here, the superconducting YBCO film shown in bright regions, combined with the degraded YBCO film in dark regions, form one or more Josephson tunnel junctions. FIGS. 4B and 4D are height mode images of the YBCO film before and after applying the +9 volts voltage through the nanoscale tip of the AFM tool. Here, the AFM tip can oscillate close to the YBCO film surface in the height mode. In this mode, the nanoscale tip intermittently touches the surface during each oscillation cycle, resulting in a small interaction force. The cantilever's deflection is used to create a topographic image of the sample surface, providing YBCO film height variation information. Before applying external voltages, the patterned YBCO film present a smooth surface, as shown in FIG. 4B. In contrast, after scanning the AFM nanoscale tip with the +9 volts voltage, the surface roughness of the YBCO film degrades, revealing a deformed YBCO film quality in the scanned region.

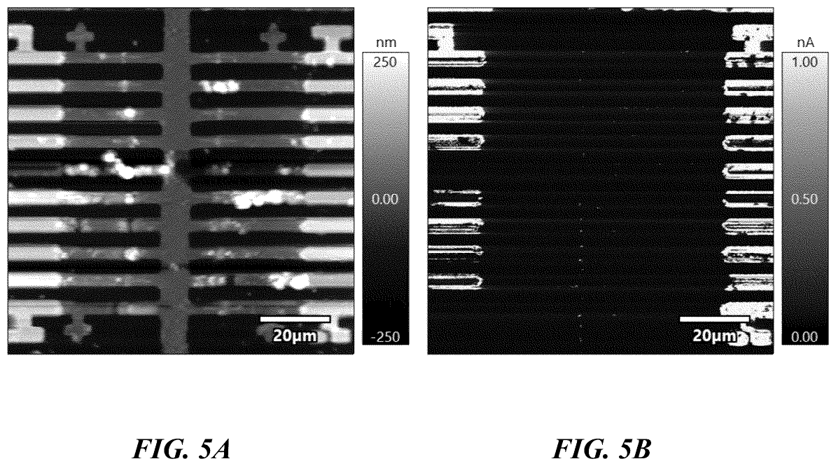

The nanoscale tip can also be scanned on the HTS YBCO film in a current mode, which is specifically configured for scanning conductive thin films. This mode involves applying a small voltage between the AFM tip and the conductive film. As the tip scans across the film's surface, the localized electrical current flowing between the tip and the film can be measured. This mode allows for the mapping of electrical conductivity variations across the thin film. FIGS. 5A and 5B illustrate a height mode image and a current mode image of a HTS YBCO film after a +9 volts AFM tip scanning, respectively. The current mode image of FIG. 5B confirms that a portion of the YBCO film has been disordered and converted to insulator after scanning the AFM tip with +9 volts external voltage, revealing non-current in the scanned region.

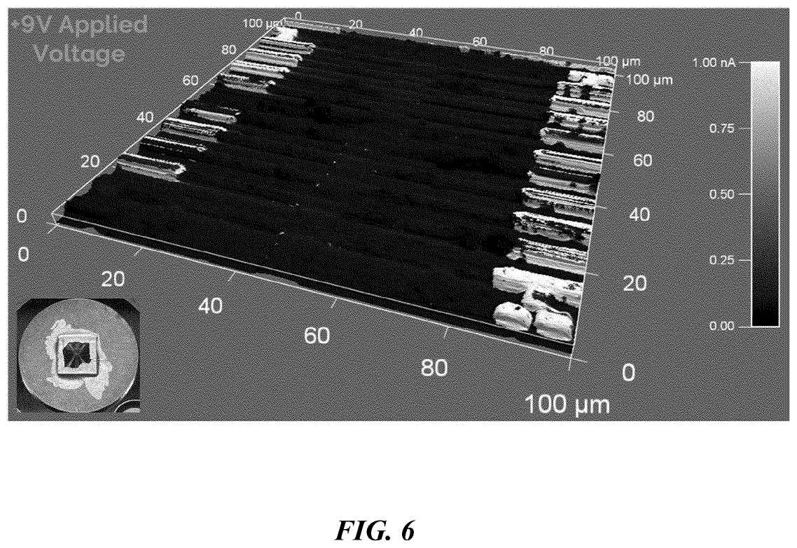

FIG. 6 shows a YBCO film before and after the application of a +9 volts voltage through a nanoscale tip. Particularly, FIG. 6 shows an overlap of a height mode image and a current mode image of the YBCO film after scanning. It can be found that the scanned YBCO film was damaged and converted to an insulator state, by using a high voltage applied through the tip. In areas where the film was scanned with a long dwell time, both the height and resistivity of the film increased. This process can be further utilized to pattern structures and Josephson tunnel junctions by carefully controlling the time and position of the nanoscale tip above a HTS sample. In comparing to conventional nanolithography technique and ion beam irradiation technique, this technique leads to a much faster and more economical approach for superconducting device fabrication.

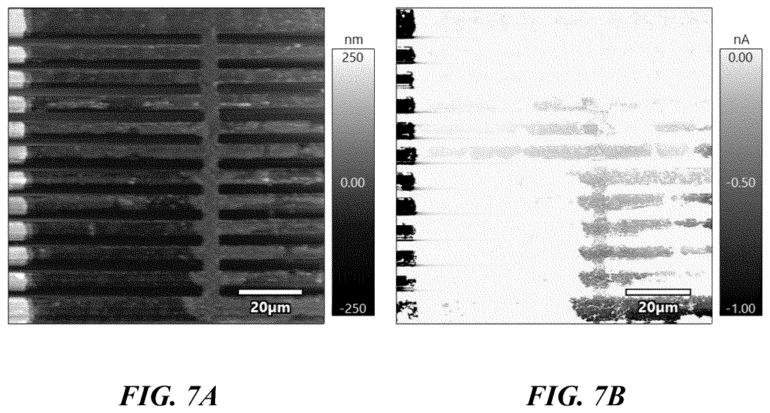

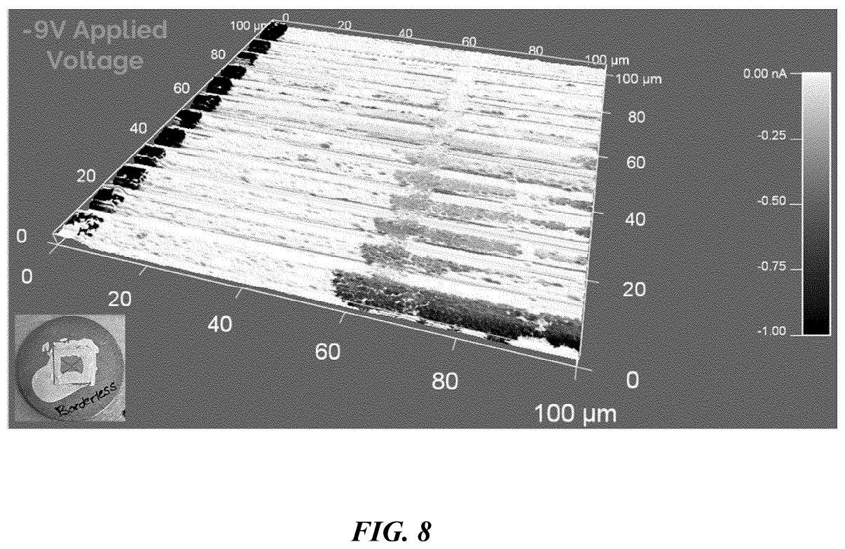

In the present technology, a negative voltage can also be used in fabricating HTS devices. For example, FIGS. 7A and 7B illustrate a height mode image and a current mode image of a HTS YBCO film after a −9 volts AFM tip scanning, respectively. The current mode image of the YBCO film on FIG. 7B confirms that the YBCO film has been converted to insulator after scanning the AFM tip with the negative voltage, revealing non-current in the scanned region. In this example, the superconducting YBCO film shown in dark regions, combined with the degraded YBCO film shown in bright regions, form one or more Josephson tunnel junctions. In addition, FIG. 8 shows an overlap of a height mode image and a current mode image of a YBCO film after the application of a −9 volts voltage through a nanoscale tip. It can be found that the scanned YBCO film was damaged and converted to insulator, by using a high negative voltage applied through the tip. In areas where the film was scanned with a long dwell time, both the height and resistivity of the film have been increased.

Various types of voltages, including a direct current voltage or an alternative current voltage, can be applied on the tip to scan on the HTS material in the present technology. A simple AFM topography and phase map obtained from the fundamental frequency mode of the cantilever reveals only the surface mechanical properties. However, chemical information or compositional sensitivity of surfaces can be extracted from higher resonant frequencies of the cantilever through Bimodal Dual AC (one of the multi-frequency AFM modes.) For example, by mapping these properties locally across the surface of the HTS material, it is possible to correlate the changes in chemical and compositional properties with the induced strain and the electrical characteristics of the Josephson tunnel junction, providing insights into the relationship between structure, chemistry, and performance of these HTS devices.

A unique capability of the voltage scan process of the present technology is that the electrical properties of the Josephson junction can be tuned from metallic to insulating by controlling the voltage levels. In particular, the energy gap of HTS material, such as a YBCO thin film, can be tuned as a function of the angle of electrode in the plane. In the present technology, the electrical measurements of the superconducting energy gap along various crystalline directions within the planes of HTS films involved the creation of multiple Josephson tunnel junctions with superconducting currents directed along different axes. External voltage applied on the HTS material can affect the copper oxide chains that run along the top and bottom of the unit cells along the b directions, therefore modifying electrical transport properties of the HTS material. FIG. 9 illustrates the variation in energy gaps of YBCO thin films, as a function of the electrode orientation within the plane. For example, FIG. 9A shows a gap anisotropy with two axes that differ by a factor of roughly 2:1. This is what one would expect from the measurement of bulk detwinned YBCO crystals that show a similar difference between the a and b crystal axes. This measurement suggests a high-quality orientated YBCO film. In contrast, FIG. 9B shows a disordered more isotropic gap and FIG. 9C shows a uni-axial highly anisotropic gap which is not expected for these materials. The helium ion micrograph in FIG. 9D, with a 25 μm field of view, depicts a typical test sample, and FIGS. 9E and 9F, with a 5 μm field of view, show the samples corresponding to FIGS. 9B and 9C, respectively. The circular and divergent lines in these images indicate the locations where the HTS devices were patterned.

Helium ion microscopy was employed to investigate the surfaces of these YBCO films of FIG. 9 in order to revealing conductivity variations. Here, insulating regions are discernible as dark areas due to the accumulation of positively charged implanted ions, which absorb the secondary electrons used in image formation. The micrograph in FIG. 9D appears smooth at a larger scale but reveals the YBCO grain structure upon closer inspection, albeit with low contrast. In addition, the micrograph shown in FIG. 9F, corresponding to the sample in FIG. 9C, displays significant contrast and distinct black veins between grains, suggesting a texture that may impede superconductivity in a specific direction. While the helium ion images of FIG. 9 reveal a lot about the grain shapes and conductivity of HTS films, it can only be used as a diagnostic after circuit fabrication and testing because the process of taking the image is a destructive one. With a similar principle, the present technology can convert, while imaging, the HTS material to an insulator through applying voltages in the same manner that they are used to create the Josephson tunnel junctions.

In the present technology, the conductive nanoscale tips can be highly customized to meet specific experimental requirements, including variations in HTS material, Josephson junction device shape, and functionalization, to enable precise manipulation and fabrication of Josephson junction device across diverse material types and application scenarios. For example, the conductive nanoscale tips described above can be designed to handle higher applied voltage to minimize or enlarge damage to a HTS material. The conductive nanoscale tip end may have a diameter ranging from 1 nm to 10 nm, or ranging from 10 nm to 100 nm. In some other examples, the conductive nanoscale tip end may have an acute angle or an obtuse angle.

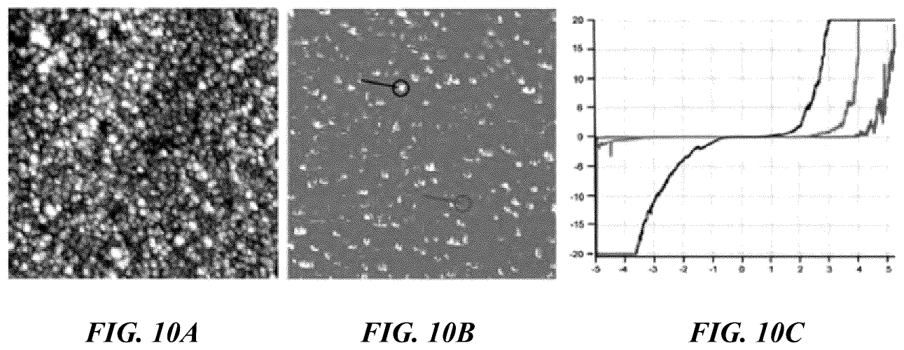

In addition, the conductive nanoscale tips can be utilized to take individual current voltage characteristics from local regions of the HTS film. For example, FIGS. 10A and 10B depict a topography image and a current image of a Europium-doped ZnO thin film sample at a bias of 1.5 volts and 2 μm scan. FIG. 10C shows corresponding current-voltage curve recorded at three specific positions indicated in FIG. 10B. In this example, a conductive atomic force microscopy (CAFM) is utilized to collect the images and to current voltage characteristics. In addition, a specimen composed of Europium doped Zinc Oxide (ZnO) is subjected to a dual-mode analysis to ascertain its topographical and electrical properties.

The sample topographical analysis as depicted in FIG. 10A, involves scanning the surface of the ZnO/Europium sample to generate a topographical map, thereby revealing the surface morphology of the sample. This aspect of the analysis is critical for understanding the physical structure of the sample at a nanometric scale. Conductive Analysis, as shown in FIG. 10B, is conducted subsequent to the topographical analysis and involves the measurement of the sample's conductive properties. This mode of analysis yields a conductive map, which exhibits the electrical texture of the sample, distinct from the surface texture observed in the topographical map. The differences between the surface and electrical textures is of particular interest and is clearly delineated in the two images.

Further, a specific region of interest within the sample can be selected for an in-depth investigation. This is achieved by measuring the current-voltage (I-V) characteristics of the selected region, as illustrated in FIG. 10C. The I-V characteristic measurement is a pivotal technique in the characterization process, as it provides valuable insights into the electrical behavior of the nano-structures, particularly those that have been subjected to applied voltage or ion irradiation. The present technology described in this disclosure enables the precise characterization of high voltage irradiated HTS nano-structures. The dual-mode analysis, comprising both topographical and conductive scanning, along with the targeted I-V characteristic measurement, provides a comprehensive understanding of the HTS devices' physical and electrical properties at the nanoscale. This level of characterization is essential for advancing the field of nanotechnology and for the development of novel nano-structured HTS tunneling devices.

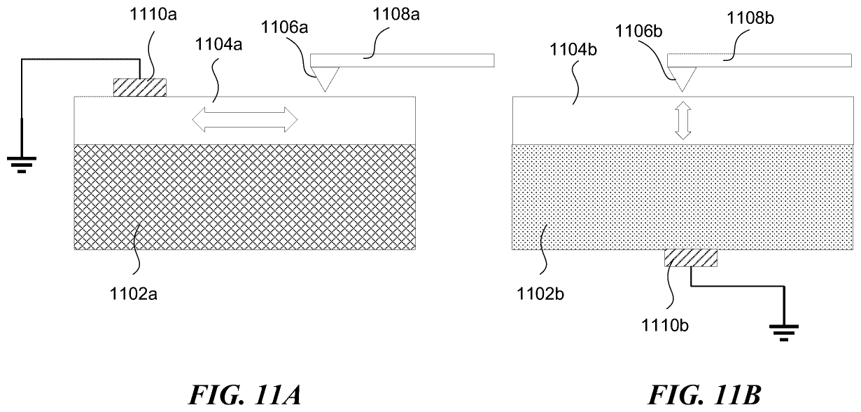

Depending on the configuration of electrodes, the external voltage can be applied on different directions of a HTS material. FIG. 11A describes an external voltage being applied along a horizontal direction, e.g., the a-b plane, of a HTS YBCO thin film. In this example, a contact electrode 1110a is formed on the top surface of the superconducting film 1104a, therefore attaching a current flow from the end of the conductive nanoscale tip 1106a and along the film length direction. Here, the conductive nanoscale tip 1106a is connected to a cantilever 1108a and can apply a voltage to the surface of the superconducting film 1104a. In this example, the voltage can be provided by a power source connected to the cantilever 1108a.

In another example, as shown in FIG. 11B, the superconducting film 1104b (e.g., a HTS YBCO thin film) can be deposited on a conductive substrate 1102b (e.g., a Nb doped SrTiO₃ substrate). Moreover, a contact electrode 1110b can be directly formed on the backside surface of the substrate 1102b. This configuration enables a current flow along the HTS YBCO film thickness direction, from the end of the conductive nanoscale tip 1106b to the contact electrode 1110b. Here, the conductive nanoscale tip 1106b is connected to a cantilever 1108b and can apply a voltage to the surface of the superconducting film 1104b. In this example, the voltage can be provided by a power source connected to the cantilever 1108b. Here, properties of the superconducting films 1104a and 1104b can be affected, e.g., changing from superconducting to insulating, in either one of above described configurations and their required threshold external voltage may be different.

In one example, a CAFM can be incorporated in the present technology for HTS devices fabrication. For example, the CAFM can include one or more conductive nanoscale tips made from materials like doped diamond, platinum-iridium, or coated silicon to ensure good conductivity while maintaining a mechanical strength and sharpness required for high-resolution imaging. The conductive nanoscale tips can be respectively mounted on one or more cantilevers and configured to scan over the HTS sample surface. The CAFM can include or is connected to a power source to apply positive or negative voltages to the HTS sample surface, through the conductive nanoscale tips and corresponding cantilevers.

In some other examples, Surface Potential Microscopies such as a Scanning Kelvin Probe Microscopy (SKPM) can be incorporated in the present technology for HTS devices fabrication. For example, the SKPM including a conductive nanoscale tip that is attached to a cantilever can be used for the HTS devices process. This conductive nanoscale tip scans the surface of the HTS sample without necessarily touching it, maintaining a constant height. A DC bias voltage can be connected to the SKPM tip and applied on specific locations on the HTS sample surface. The conductive nanoscale tip used in SKPM can be made of platinum-iridium, gold, or doped diamond, for good durability, stability, and conductivity.

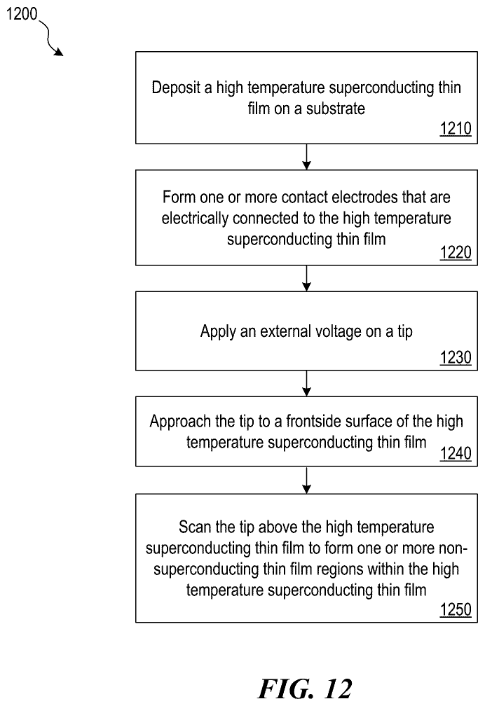

FIG. 12 is a flow chart illustrating a method 1200 for fabricating a high-temperature superconducting device in accordance with various embodiments of the present technology. The method 1200 includes depositing a high temperature superconducting thin film on a substrate, at 1210. For example, the HTS YBCO thin film 1104a can be deposited on the substrate 1102a, as shown in FIG. 11A.

In addition, the method 1200 includes forming one or more contact electrodes that are electrically connected to the high temperature superconducting thin film, at 1220. For example, the contact electrode 1110a can be formed on the frontside surface of the HTS YBCO thin film 1104a, as shown in FIG. 11A. In another example shown in FIG. 11B, the contact electrode 1110b can be formed on the backside of the conductive substrate 1102b and electrically connected to the HTS YBCO thin film 1104b.

The method 1200 also includes applying an external voltage on a tip, at 1230. For example, a positive voltage or a negative voltage can be applied on the conductive nanoscale tips 1106a and 1106b, respectively through their corresponding cantilevers 1108a and 1108b, as shown in FIGS. 11A and 11B.

Further, the method 1200 includes approaching the tip to a frontside surface of the high temperature superconducting thin film, at 1240. For example, the conductive nanoscale tip 1106a can be moved to approach the frontside surface of the HTS YBCO thin film 1104a, through adjusting the position of the corresponding cantilever 1108a, as shown in FIG. 11A.

Lastly, the method 1200 includes scanning the tip above the high temperature superconducting thin film to form one or more non-superconducting regions within the high temperature superconducting thin film, at 1250. For example, the conductive nanoscale tip 1106a can be configured to scan along a scan path on the frontside surface of the HTS YBCO thin film 1104a. The movement of the conductive nanoscale tip 1106a can be controlled and driven by a motor connected to its corresponding cantilever 1108a. With the applied voltage, the scanned region of the HTS YBCO thin film 1104a can be converted from superconductor to insulator, through degrading or disordering of the HTS YBCO material quality.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A high temperature superconducting device, comprising:
a substrate;
a high temperature superconducting thin film disposed on the substrate; and
one or more non-superconducting thin film regions formed adjacent to and across a substantially entire thickness of the high temperature superconducting thin film,
wherein the one or more non-superconducting thin film regions are formed from degrading corresponding superconducting materials same to the high temperature superconducting thin film through applying an external voltage, and
wherein the one or more non-superconducting thin film regions and the high temperature superconducting thin film form one or more Josephson tunnel junctions.

2. The high temperature superconducting device of claim 1, wherein the high temperature superconducting thin film is made of materials including: Yttrium Barium Copper Oxide, Bismuth Strontium Calcium Copper Oxide, Thallium Barium Calcium Copper Oxide, Mercury Barium Calcium Copper Oxide, Magnesium Diboride, or a combination thereof.

3. The high temperature superconducting device of claim 1, wherein the one or more non-superconducting thin film regions include non-superconducting Josephson tunnel junctions that are formed by applying an external voltage thereon through a tip.

4. The high temperature superconducting device of claim 3, wherein the tip is configured to scan on a frontside surface of the superconducting thin film while applying the external voltage.

5. The high temperature superconducting device of claim 4, wherein the external voltage ranges from 100 mV to 10V.

6. The high temperature superconducting device of claim 3, wherein the external voltage is a direct current (DC) voltage or an alternative current (AC) voltage.

7. The high temperature superconducting device of claim 3, wherein the tip has a diameter ranging from 1 nm to 100 nm.

8. The high temperature superconducting device of claim 3, wherein the tip may have an acute angle or an obtuse angle on its end.

9. The high temperature superconducting device of claim 1, wherein the non-superconducting Josephson tunnel junctions have widths on an order of 1 nm.

10. The high temperature superconducting device of claim 1, wherein the external voltage is applied along various axes of the high temperature superconducting thin film to form the one or more Josephson tunnel junctions.

11. The high temperature superconducting device of claim 1, further comprising a superconducting nanowire, the superconducting nanowire being surrounded by at least two of the one or more non-superconducting thin film regions of the high temperature superconducting thin film.

12. An apparatus for fabricating high temperature superconducting devices, comprising:
a sample stage configured to hold a high temperature superconducting sample;
a power source configured to provide direct current (DC) voltages or an alternative current (AC) voltages;
one or more cantilevers connected to the power source; and
one or more conductive nanoscale tips disposed on one end of corresponding one or more cantilevers,
wherein the one or more conductive nanoscale tips are configured to scan along a frontside surface of the high temperature superconducting sample while applying a DC voltage or an AC voltage provided by the power source, and
wherein one or more non-superconducting regions are formed in the high temperature superconducting sample according to scan path of the one or more conductive nanoscale tips.

13. A method of forming a high temperature superconducting device, comprising:
depositing a high temperature superconducting thin film on a substrate;
forming one or more contact electrodes that are electrically connected to the high temperature superconducting thin film;
applying an external voltage on a tip;
approaching the tip to a frontside surface of the high temperature superconducting thin film; and
scanning the tip above the high temperature superconducting thin film to form one or more non-superconducting thin film regions within the superconducting thin film.

14. The method of claim 13, wherein the external voltage is applied on an Atomic Force Microscopy probe tip, and wherein the tip has a diameter ranging from 1 nm to 100 nm.

15. The method of claim 13, wherein approaching the tip to the high temperature superconducting thin film includes physically contacting the tip to the frontside surface of the high temperature superconducting thin film.

16. The method of claim 13, wherein the external voltage is applied along an in-plane direction of the high temperature superconducting thin film.

17. The method of claim 16, wherein the one or more contact electrodes are disposed on the frontside surface of the high temperature superconducting thin film.

18. The method of claim 13, wherein the external voltage is applied along an out-of-plane direction of the high temperature superconducting thin film.

19. The method of claim 18, wherein the one or more contact electrodes are disposed on the substrate.

20. The method of claim 13, further comprising removing the one or more contact electrodes from the high temperature superconducting thin film.
